(19) United States
(12) Patent Application Publication
(10) Pub. No.: US 2009/0004877 A1
(43) Pub. Date: Jan. 1, 2009

(54) SUBSTRATE PROCESSING APPARATUS AND SEMICONDUCTOR DEVICE MANUFACTURING METHOD

(75) Inventor: Masayuki ASAI, Toyama-Shi (JP)

Correspondence Address: BIRCH STEWART KOLASCH & BIRCH, PO BOX 747, FALLS CHURCH, VA, 22040-0747, US

(73) Assignee: HITACHI KOKUSAI ELECTRIC INC., Tokyo (JP)

(21) Appl. No.: 12/147,209

(22) Filed: Jun. 26, 2008

(30) Foreign Application Priority Data
Jun. 28, 2007 (JP) 2007-170454
Jun. 19, 2008 (JP) 2008-160058

(51) Int. Cl. B05C 11/00; H01L 21/30

(52) U.S. Cl. 438/758; 118/710; 257/E21.211

(57) ABSTRACT

Disclosed is a substrate processing apparatus which includes: a processing chamber to process a substrate; an exhaust path to exhaust the processing chamber; an exhaust device; an exhaust valve to open and close the exhaust path; a raw material gas supply member to supply raw material gas which contributes to film forming into the processing chamber; a cleaning gas supply member to supply cleaning gas which removes an accretion which adheres to an inside of the processing chamber with the raw material gas being supplied, the cleaning gas supply member comprising a supply path to supply the cleaning gas to the processing chamber and a supply valve to open and close the supply path; and a control section which controls the exhaust valve and the supply valve to supply the cleaning gas from the supply path to the processing chamber with exhaustion of the processing chamber being stopped.

### BACKGROUND OF THE INVENTION

1. Field of the Invention

The present invention relates to a substrate processing apparatus and a semiconductor device manufacturing method, and more particularly, to a substrate processing apparatus and a semiconductor device manufacturing method which supply raw material gas, which is to form a desired film, onto a substrate surface to form the desired film on the substrate surface.

2. Description of the Related Art

In the substrate processing apparatus of this kind, when raw material gas is supplied, the raw material gas flows also to other portions (e.g., an inner wall of a processing chamber) in addition to a surface of the substrate, and an unnecessary film is accumulatively deposited as accretions. Impurities, which are not harmless to substrate processing, may be mixed in the accretions. In this case, there is a possibility that the accretions cause foreign matter contamination of a substrate.

That is, if the accretions are influenced by thermal energy generated by successive processings of the substrate and are annealed, there are times when impurities are separated from the accretions, contraction and expansion of the accretions are repeated and a microcrack is generated and impurities are separated from the microcrack, or impurities themselves are separated from the deposited portion. At these times, it is conceived that impurities or accretions including the impurities float in the processing chamber or a member (e.g., a gas supply tube) which is in communication with the processing chamber, and this causes foreign matter contamination. When the substrate is processed, it is conceived that a depositing amount of accretions is proportionally increased and the possibility that the foreign matter contamination is caused is more and more increased as the processing temperature of the substrates becomes lower, as the supply speed of the raw material gas is increased or as a thickness of a film to be formed on a surface of a substrate is increased.

Hence, to prevent or suppress the above-mentioned problems, separate from supplying the raw material gas into the processing chamber, cleaning gas for removing the accretions in the processing chamber is supplied into the processing chamber (especially to a portion where it is estimated that accretions are adhering) to convert the accretions into harmless gas and the gas is exhausted as it is. That is, self cleaning is carried out. For example, when a SiN film is formed on a surface of a substrate, NF₃ gas is supplied as cleaning gas to the accretions (SiN film), which are a generation source of the foreign matter contamination, to forcibly react the SiN and NF₃ with each other, the accretions are converted into SiF₄ gas and N₂ gas, and these gases are exhausted.

According to the method using the above-mentioned self cleaning, however, a region where the cleaning gas can not flow easily (dead space) is formed in the processing chamber, and accretions are prone to be deposited in the dead space. This is a phenomenon which can be caused also by a structure in the processing chamber or flow velocity of cleaning gas, it is difficult to completely solve this problem, and the possibility that the dead space is formed can not be eliminated no matter what the structure in the processing chamber or the flow velocity of the cleaning gas is changed. Therefore, it is necessary to take measures to suppress the generation of the foreign matter contamination. For example, it is necessary to set the supply time of cleaning gas longer than usual time, to periodically exchange a constituting member of the processing chamber, or to carry out another processing such as wet cleaning processing in addition to the supply of the cleaning gas. As a result, the efficiency (productivity) of the substrate processing is deteriorated.

### SUMMARY OF THE INVENTION

Hence, it is a main object of the present invention to provide a substrate processing apparatus and a manufacturing method of a semiconductor device capable of restraining a dead space from being formed in a processing chamber.

According to one aspect of the present invention, there is provided a substrate processing apparatus, comprising:

a processing chamber to process a substrate;

an exhaust path to exhaust the processing chamber;

an exhaust device to exhaust atmosphere in the processing chamber through the exhaust path;

an exhaust valve to open and close the exhaust path;

a raw material gas supply member to supply raw material gas which contributes to film forming into the processing chamber;

a cleaning gas supply member to supply cleaning gas which removes an accretion, which adheres to an inside of the processing chamber with the raw material gas being supplied, the cleaning gas supply member comprising a supply path to supply the cleaning gas to the processing chamber and a gas supply valve to open and close the supply path; and

a control section which controls the exhaust valve and the gas supply valve to supply the cleaning gas from the supply path to the processing chamber with exhaustion of the processing chamber being stopped.

According to another aspect of the present invention, there is provided a substrate processing apparatus, comprising:

a processing chamber to process a substrate;

a heating member disposed outside the processing chamber to heat an inside of the processing chamber;

an exhaust path to exhaust the processing chamber;

an exhaust device to exhaust atmosphere in the processing chamber through the exhaust path;

an exhaust valve to open and close the exhaust path;

a raw material gas supply member to supply raw material gas which contributes to film forming into the processing chamber;

a cleaning gas supply member to supply cleaning gas which removes an accretion, which adheres to an inside of the processing chamber with the raw material gas being supplied; and

a control section, wherein

the cleaning gas supply member comprises:
a first supply path to supply the cleaning gas to the processing chamber;
a first gas supply valve to open and close the first supply path;
a second supply path communicating with a lower portion of the processing chamber at a position lower than the heating member to supply the cleaning gas to the processing chamber; and
a second gas supply valve to open and close the second supply path,

the raw material gas supply member comprises:
a third supply path connected with the first supply path at a downstream side of the first gas supply valve to supply a first raw material gas of the raw material gas;
a third gas supply valve to open and close the third supply path;
a fourth supply path to supply a second raw material gas of the raw material gas to the processing chamber, the second raw material gas being different from the first raw material gas; and
a fourth gas supply valve to open and close the fourth supply path, and

the control section controls the exhaust valve, the third gas supply valve and the fourth gas supply valve to alternatively supply the first raw material gas and the second raw material gas when the first raw material gas and the second raw material gas are supplied to form a desired film on the substrate, and

the control section controls the exhaust valve, the first gas supply valve and the second gas supply valve to supply the cleaning gas from the first supply path and the second supply path to the processing chamber with exhaustion of the processing chamber being stopped when the cleaning gas is supplied.

According to still another aspect of the present invention, there is provided a substrate processing apparatus, comprising:

a processing chamber to process a substrate;

an exhaust path to exhaust the processing chamber;

an exhaust device to exhaust atmosphere in the processing chamber through the exhaust path;

an exhaust valve to open and close the exhaust path;

a raw material gas supply member to supply raw material gas which contributes to film forming into the processing chamber;

a cleaning gas supply member to supply cleaning gas which removes an accretion, which adheres to an inside of the processing chamber with the raw material gas being supplied, the cleaning gas supply member comprising:
a first supply path to supply the cleaning gas;
a second supply path branching from the first supply path and comprising a first gas supply valve, a first gas reservoir to store the cleaning gas and the second gas supply valve in this order from upstream;
a third supply path branching from the first supply path and comprising a third gas supply valve, a second gas reservoir to store the cleaning gas and the fourth gas supply valve in this order from upstream; and
a fourth supply path to which the second supply path and the third supply path are joined to supply the cleaning gas to the processing chamber; and

a control section which controls the exhaust valve, the first gas supply valve, the second gas supply valve, the third gas supply valve and the fourth gas supply valve to repeat predetermined times a step of supplying the cleaning gas to the second supply path to store the cleaning gas in the first gas reservoir and supplying the cleaning gas stored in the first gas reservoir to the processing chamber from the first gas reservoir with exhaustion of the processing chamber being stopped, and a step of supplying the cleaning gas to the third supply path to store the cleaning gas in the second gas reservoir and supplying the cleaning gas stored in the second gas reservoir to the processing chamber from the second gas reservoir with exhaustion of the processing chamber being stopped.

According to still another aspect of the present invention, there is provided a semiconductor device manufacturing method, comprising:

supplying raw material gas to a substrate accommodated in a processing chamber to form a desired film on the substrate; and

supplying cleaning gas to the processing chamber with exhaustion of the processing chamber being stopped.

### BRIEF DESCRIPTION OF DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a perspective view showing a schematic structure of a substrate processing apparatus according to a preferred embodiment of the present invention;

FIG. 2 is a schematic diagram showing structures of a vertical type processing furnace and members coming with the processing furnace used in the preferred embodiment of the present invention, and is a vertical sectional view of a processing furnace portion taken along its vertical direction;

FIG. 3 is a schematic diagram showing the structure of the vertical type processing furnace used in the preferred embodiment of the present invention, and is a transverse sectional view of the processing furnace portion taken along its horizontal direction;

FIG. 4 is a schematic diagram showing a relation between time and a pressure in a processing chamber at the time of cleaning in the preferred embodiment of the present invention and its comparative example;

FIG. 5 is a vertical sectional view for explaining a dead space in the vertical type processing furnace used in the preferred embodiment of the present invention;

FIG. 6 is a transverse sectional view for explaining the dead space in the vertical type processing furnace used in the preferred embodiment of the present invention;

FIG. 7 is a diagram for explaining an example when two gas reservoirs are provided in parallel;

FIG. 8 is a sequence diagram for explaining a case where cleaning gas is supplied from both a nozzle provided in the processing chamber and a short tube connected to a lower portion of the processing chamber, and two gas reservoirs provided upstream from the nozzle in parallel and a gas reservoir provided upstream from the short tube are used;

FIG. 9 is a sequence diagram for explaining a case where cleaning gas is supplied from both the nozzle provided in the processing chamber and the short tube connected to the lower portion of the processing chamber, and a gas reservoir provided upstream from the nozzle and the gas reservoir provided upstream from the short tube are used;

FIG. 10 is a sequence diagram for explaining a case where cleaning gas is supplied only from the nozzle provided in the processing chamber, and only the gas reservoir provided upstream from the nozzle is used;

FIG. 11 is a sequence diagram for explaining a case where cleaning gas is supplied from both the nozzle provided in the processing chamber and the short tube connected to the lower portion of the processing chamber, and the gas reservoir provided upstream from the nozzle in parallel and the gas reservoir provided upstream from the short tube are not used;

FIG. 12 is a sequence diagram for explaining a case where cleaning gas is supplied only from the nozzle provided in the processing chamber, and the gas reservoir provided upstream from the nozzle is not used; and

FIG. 13 is a diagram showing a schematic structure of a comparative example of the processing furnace and members coming with the processing furnace shown in FIG. 2.

### DESCRIPTION OF THE PREFERRED EMBODIMENTS

Next, preferred embodiments of the present invention will be explained with reference to the drawings.

A substrate processing apparatus according the present embodiment is constituted as a semiconductor device manufacturing apparatus, as one example, which is used for manufacturing a semiconductor device integrated circuit (IC). In the following description, a case in which a vertical type apparatus which subjects a substrate to a thermal processing and the like and which is used as one example of the substrate processing apparatus will be described.

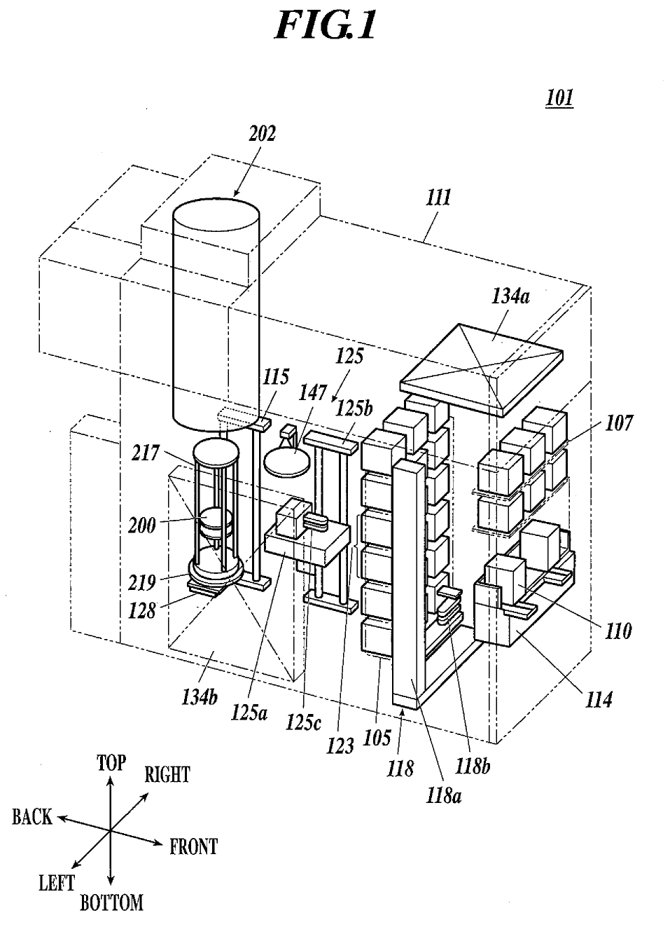

As shown in FIG. 1, a processing apparatus 101 uses cassettes 110 which accommodate wafers 200, which are one example of the substrate. The wafers 200 are made of a material such as silicon. The substrate processing apparatus 101 includes a casing 111 and a cassette stage is disposed inside the casing 111. The cassette 110 is transferred onto the cassette stage 114 and carried out from the cassette stage 114 by a transportation apparatus in plant (not shown).

The cassette 110 is placed on the cassette stage 114 by the transportation apparatus in plant such that the wafers 200 in the cassette 110 are in their vertical attitudes and an opening of the cassette 110 for taking wafers in and out is directed upward. The cassette stage 114 is constituted such that it rotates the cassette 110 clockwise in the vertical direction by 90° to rearward of the casing, the wafers 200 in the cassette 110 are in their horizontal attitudes, and the opening of the cassette 110 for taking wafers in and out is directed to rearward of the casing.

Cassette shelves 105 are disposed substantially at a central portion in the casing 111 in its front and back direction, and the cassette shelves 105 store a plurality of cassettes 110 in a plurality of rows and a plurality of lines. The cassette shelves 105 are provided with transfer shelves 123 in which the cassettes 110 to be transferred by a wafer transferring mechanism 125 are to be accommodated.

Auxiliary cassette shelves 107 are provided above the cassette stage 114 to subsidiarily store the cassettes 110.

A cassette transfer device 118 is provided between the cassette stage 114 and the cassette shelves 105. The cassette transfer device 118 includes a cassette elevator 118a capable of vertically moving while holding the cassette 110, and a cassette transfer mechanism 118b as a transfer mechanism. The cassette transfer device 118 is constituted to transfer the cassette 110 between the cassette stage 114, the cassette shelves 105 and the auxiliary cassette shelves 107 by a continuous motion of the cassette elevator 11a and the cassette transfer mechanism 118b.

A wafer transferring mechanism 125 is provided behind the cassette shelves 105. The wafer transferring mechanism 125 includes a wafer transferring device 125a which can rotate and straightly move the wafer 200 in the horizontal direction, and a wafer transferring device elevator 125b which vertically moves the wafer transferring device 125a. The wafer transferring device 125a is provided with tweezers 125c for picking up the wafer 200. The wafer transferring mechanism 125 is constituted such that the tweezers 125c as a placing portion of the wafers 200 charges a boat 217 with wafers 200 and discharges the wafers 200 from the boat 217 by continuous motion of the wafer transferring device elevator 125b and the wafer transferring device 125a.

A processing furnace 202 for heat treating the wafers 200 is provided at a rear and upper portion in the casing 111. A lower end of the processing furnace 202 is opened and closed by a furnace opening shutter 147.

A boat elevator 115 is provided below the processing furnace 202 for vertically moving the boat 217 to and from the processing furnace 202. An arm 128 is connected to an elevating stage of the boat elevator 115 and a seal cap 219 is horizontally set up on the arm 128. The seal cap 219 vertically supports the boat 217, and can close a lower end of the processing furnace 202.

The boat 217 includes a plurality of holding members, and horizontally holds a plurality of wafers 200 (e.g., about 50 to 150 wafers) which are arranged in the vertical direction such that centers thereof are aligned with each other.

A clean unit 134a is provided above the cassette shelves 105 for supplying clean air which is a purified atmosphere. The clean unit 134a includes a supply fan and a dustproof filter so that the clean air flows into the casing 111.

A clean unit 134b for supplying clean air is provided on a left side end of the casing 111. The clean unit 134b comprises a supply fan and a dustproof filter so that the clean air flows by the wafer transferring device 125a, the boat 217 and so forth. The clean air is exhausted outside the casing 111 after flowing near the wafer transferring device 125a, the boat 217 and so forth.

Next, main operations of the substrate processing apparatus 101 will be explained.

When the cassette 110 is transferred onto the cassette stage 114 by the transportation apparatus in plant (not shown), the cassette 110 is placed on the cassette stage 114 such that the wafers 200 are in their vertical attitudes and the opening of the cassette 110 for taking wafers in and out is directed upward. Then, the cassette 110 is rotated clockwise in the vertical direction by 90° to rearward of the casing 111 so that the wafers 200 in the cassette 110 are in their horizontal attitudes, and the opening of the cassette 110 for taking wafers in and out is directed to rearward of the casing 111.

Next, the cassette 110 is automatically transferred onto a designated shelf position of the cassette shelves 105 and the auxiliary cassette shelves 107 by the cassette transfer device 118, and the cassette 110 is temporarily stored. After that, the cassette 110 is transferred onto the transfer shelves 123 from the cassette shelves 105 or the auxiliary cassette shelves 107 by the cassette transfer device 118, or directly transferred onto the transfer shelves 123.

When the cassette 110 is transferred onto the transfer shelves 123, the wafers 200 are picked up from the cassette 110 through the opening for taking wafers in and out by the tweezers 125c of the wafer transferring device 125a, and the boat 217 is charged with the wafers 200. The wafer transferring device 125a which delivered the wafers 200 to the boat 217 returns to the cassette 110, and charges the boat 217 with the next wafers 200.

When the boat 217 is charged with a predetermined number of wafers 200, the furnace opening shutter 147, which has closed a lower end portion of the processing furnace 202 is opened to open the lower end portion of the processing furnace 202. Then, the boat 217 which holds the wafers 200 is loaded into the processing furnace 202 by upward movement of the boat elevator 115 and the lower portion of the processing furnace 202 is closed by the seal cap 219.

After the loading, the wafers 200 are subjected to thermal processing in the processing furnace 202.

After the thermal processing, the wafers 200 and the cassette 110 are carried outside the casing 111 by reversing the above-described procedure.

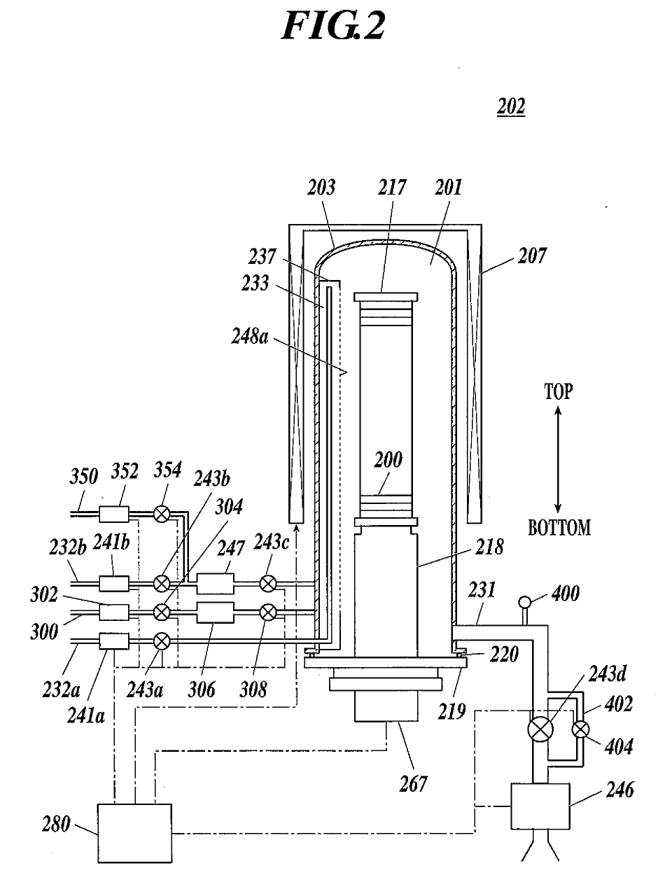

As shown in FIG. 2, the processing furnace 202 is provided with a heater 207, which is a heating device. A reaction tube 203 for processing the wafers 200 as substrates is provided inside the heater 207. A lower end opening of the reaction tube 203 is air-tightly closed by a seal cap 219 as a lid through an O-ring 220. A processing chamber 201 is formed by at least the reaction tube 203 and the seal cap 219.

A boat 217 which is a substrate holding member stands on the seal cap 219 through a boat support stage 218. The boat support stage 218 is a holding body which holds the boat 217. The boat 217 is inserted into the processing chamber 201. A plurality of wafers 200, which are to be subjected to batch process, are stacked on the boat 217 in a horizontal attitude in multi-layers in the vertical direction in FIG. 2. The heater 207 heats the wafers 200 inserted into the processing chamber 201 to a predetermined temperature.

Two raw material gas supply tubes 232a and 232b are connected to a lower portion of the processing chamber 201 for supplying a plurality of kinds of (in the present embodiment, two kinds of) gases.

The raw material gas supply tube 232a is provided with a mass flow controller 241a which is a flow rate control device and a valve 243a which is an on-off valve. A raw material gas is flowed into the raw material gas supply tube 232a and the raw material gas is supplied to the processing chamber 201 through a later-described buffer chamber 237 formed in the reaction tube 203.

The raw material gas supply tube 232b is provided with a mass flow controller 241b which is a flow rate control device, a valve 243b which is an on-off valve, a gas reservoir 247 and a valve 243c which is an on-off valve. A raw material gas is flowed into the raw material gas supply tube 232b and the raw material gas is supplied to the processing chamber 201 through a later-described gas supply section 249.

A cleaning gas supply tube 300 is connected to a lower portion of the processing chamber 201. Cleaning gas is supplied through the cleaning gas supply tube 300. The cleaning gas is for removing accretions which adhere to the processing chamber 201.

The cleaning gas supply tube 300 is provided with a mass flow controller 302 which is a flow rate control device, a valve 304 which is an on-off valve, a gas reservoir 306 and a valve 308 which is an on-off valve. The cleaning gas is flowed into the cleaning gas supply tube 300 and the cleaning gas is supplied to the processing chamber 201.

A cleaning gas supply tube 350 which supplies the same cleaning gas as the above-mentioned cleaning gas is connected to the gas supply tube 232b in addition to the cleaning gas supply tube 300. The cleaning gas supply tube 350 is connected in between the gas reservoir 247 and the valve 243b of the gas supply tube 232b. The cleaning gas supply tube 350 is provided with a mass flow controller 352 which is a flow rate control device and a valve 354 which is an on-off valve. Cleaning gas flows into the cleaning gas supply tube 350, and the cleaning gas is supplied to the processing chamber 201 through the gas supply tube 232b and a gas supply section 249 (which will be described later).

As explained above, the cleaning gas supply tube 350 is connected to the gas supply tube 232b between the valve 243b and the gas reservoir 247. Considering the downstream portion from the connecting point, the raw material gas and the cleaning gas are supplied to the processing chamber 201 through the gas supply tube 232b, the valve 243c, the gas reservoir 247, a nozzle 234 (which will be described later) and the gas supply section 249 (which will be described later). Therefore, if the view is changed, it can be conceived that the cleaning gas supply tube 350 is connected to the nozzle 234 (which will be described later), the cleaning gas supply tube 350 is provided with the valve 354, the gas reservoir 247 and the valve 243c in this order from the upstream, and the gas supply tube 232b is connected to the cleaning gas supply tube 350 between the valve 354 and the gas reservoir 247.

The processing chamber 201 is connected to one end of a gas exhaust tube 231 which exhausts gas atmosphere in the processing chamber 201. The gas exhaust tube 231 is provided with a valve 243d. The other end of the gas exhaust tube 231 is connected to a vacuum pump 246 so that the inside of the processing chamber 201 is evacuated. The valve 243d is an on-off valve to evacuate the processing chamber 201 and to stop the evacuation by opening and closing the valve 243d, and capable of adjusting the pressure in the processing chamber 201 by adjusting valve opening.

The gas exhaust tube 231 is provided with a vacuum gage 400 which measures a degree of vacuum (pressure) in the processing chamber 201. The gas exhaust tube 231 is also provided with a gas exhaust tube 402 such as to bypass a valve 243d. One end of the gas exhaust tube 402 is connected to the gas exhaust tube 231 at a location upstream from the valve 243d, and the other end of the gas exhaust tube 402 is connected to the gas exhaust tube 231 at a location downstream from the valve 243d. The gas exhaust tube 402 is provided with a valve 404. A diameter of the gas exhaust tube 402 is smaller than that of the gas exhaust tube 231. When the same kind of gas flows through the gas exhaust tubes 231 and 402 at the same velocity, the exhaust amount of gas (flow rate per unit time) through the gas exhaust tube 402 is smaller than that through the gas exhaust tube 231.

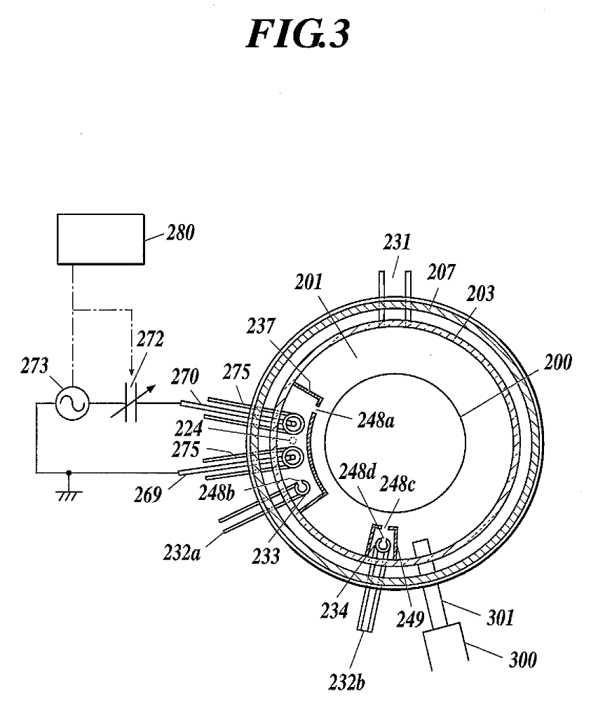

As shown in FIG. 3, a buffer chamber 237 which is a gas dispersing space is provided in an arc space between wafers 200 and an inner wall of the reaction tube 203 constituting the processing chamber 201. The buffer chamber 237 extends along the vertical direction in FIG. 2. As shown in FIG. 3, a wall constituting the buffer chamber 237 is opposed to the wafers 200. An end of a wall which constitutes the buffer chamber 237 and which is opposed to the wafers 200 is formed with first gas supply holes 248a for supplying gas. The gas supply holes 248a are opened toward the center of the reaction tube 203. The gas supply holes 248a have the same opening areas from the lower portion to the upper portion, and they have the same opening pitches.

A nozzle 233 is disposed at an end of the buffer chamber 237 opposite from the end where the first gas supply holes 248a are provided. The nozzle 233 extends along the vertical direction in FIG. 2 from a lower portion to an upper portion of the reaction tube 203. The nozzle 233 is provided with gas supply holes 248b which are supply holes for supplying gas. When a pressure difference between the buffer chamber 237 and the processing chamber 201 is small, opening areas of the gas supply holes 248b are the same and the opening pitches are also the same from upstream side to downstream side of gas, but when the pressure difference is great, the opening areas are increased or the opening pitches are reduced from the upstream side toward the downstream side.

In the present embodiment, the opening areas of the second gas supply holes 248b are gradually increased from the upstream side toward the downstream side. With this structure, when the gases are blown out from the respective gas supply holes 248b into the buffer chamber 237, the gases have different flow velocities but substantially the same flow rates. Then, the differences between particle velocities of the gases are moderated in the buffer chamber 237, and the gases are blown into the processing chamber 201 from the first gas supply holes 248a. Therefore, when the gases blown out from the respective second gas supply holes 248b blow out from the respective first gas supply holes 248a, the gases have equal flow rates and flow velocities.

Two rod-like electrodes 269 and 270 having a thin and long structure are disposed in the buffer chamber 237. The rod-like electrodes 269 and 270 extend from an upper portion toward a lower portion in FIG. 2. The electrodes 269 and 270 are covered by electrode protecting tubes 275 for protecting the electrodes. One of the rod-like electrodes 269 and 270 is connected to a high frequency power supply 273 through a matching device 272, and the other one is connected to the ground which is a reference potential. When voltage is applied between the electrodes 269 and 270, plasma is generated in a plasma generating region 224 between the rod-like electrodes 269 and 270.

The electrode protecting tubes 275 can be inserted into the buffer chamber 237 in a state where the rod-like electrodes 269 and 270 are isolated from an atmosphere in the buffer chamber 237. If the atmosphere in the electrode protecting tubes 275 is the same as outside air (atmosphere), the rod-like electrodes 269 and 270 inserted into the electrode protecting tubes 275 are oxidized by heat of the heater 207. For this reason, in the present embodiment, an inert gas purge mechanism (not shown) is provided for preventing the rod-like electrodes 269 and 270 from being oxidized, and an inert gas such as nitrogen is charged or purged into the electrode protecting tubes 275, suppressing oxygen density to a sufficient low level.

As shown in FIG. 3, the gas supply section 249 is provided at an inner wall of the reaction tube 203. The gas supply section 249 is provided at a position away from a position of the first gas supply holes 248a by about 120° with the center portion of the reaction tube 203 as the center. The gas supply section 249 is a supply section for sharing supply gas kinds with the buffer chamber 237 when supplying a plurality of kinds of gases alternately to the wafers 200 one kind by one kind in film formation by the ALD method.

The gas supply section 249 also includes gas supply holes 248c, which are supply holes for supplying gas, at locations opposed to the wafers 200. The gas supply holes 248c extend along the vertical direction in FIG. 2. A nozzle 234 is disposed inside the gas supply section 249. The nozzle 234 extends from an upper portion to a lower portion along the vertical direction in FIG. 2. The nozzle 234 is provided with gas supply holes 248d which are supply holes for supplying gas.

When a pressure difference between the inside of the gas supply section 249 and inside of the processing chamber 201 is small, opening areas of the gas supply holes 248c may be the same and the opening pitches may be also the same from upstream side to downstream side of gas, but when the pressure difference is great, the opening areas should be increased or the opening pitches should be reduced from the upstream side toward the downstream side. In the present embodiment, the opening areas of the gas supply holes 248c are gradually increased from the upstream side toward the downstream side.

A raw material gas supply tube 232b is connected to a lower portion of the nozzle 234 in the gas supply section 249, and the cleaning gas supply tube 300 is connected to a lower portion of the processing chamber 201. A tip end of the cleaning gas supply tube 300 is connected to a quartz short tube 301. The short tube 301 is in communication with a lower portion of the processing chamber 201 at a location lower than the heater 207. An inner diameter (tube diameter) of the short tube 301 is about ½ of that of the cleaning gas supply tube 300.

As shown in FIG. 2, a boat 217 is provided at a central portion in the reaction tube 203. The plurality of wafers 200 are to be placed on the boat 217 in multi-layers at an equal distance from each other. The boat 217 can be loaded into and unloaded from the reaction tube 203 by a boat elevator mechanism (not shown). Further, to enhance the uniformity of the processing, there is provided, under the boat 217, a boat rotating mechanism 267 which is a rotating device for rotating the boat 217. By rotating the boat rotating mechanism 267, the boat 217 held by a quartz supporting stage 218 is rotated.

A controller 280, which is control means, is connected to the mass flow controllers 2411a, 241b, 302 and 352, the valves 243a, 243b, 243c and 243d, 304, 308, 354 and 404, the heater 207, the vacuum pump 246, the boat rotating mechanism 267, the boat elevator 115, the high frequency power supply 273 and the matching device 272 and so forth. In the present embodiment, the controller 280 controls the adjustment of flow rates of the mass flow controllers 241a, 241b, 302 and 352, controls opening and closing of the valves 243a, 243b, 243c 304, 308, 354 and 404, controls opening and closing and the pressure adjustment of the fourth valve 243d, controls temperature adjustment of the heater 207, controls actuation and stop of the vacuum pump 246, controls adjustment of rotation speed of the boat rotating mechanism 267, controls the vertical movement of the boat elevator 115, controls electricity supply of the high frequency power supply 273, and controls impedance by the matching device 272.

Next, a film forming example using the ALD method will be explained giving an example of forming a SiN film using DCS and NH₃ gases as one of producing methods of a semiconductor device.

The ALD (Atomic Layer Deposition) method which is one of CVD (Chemical Vapor Deposition) methods is a technique in which two (or more) kinds of raw material gases used for forming films are alternately supplied onto a substrate one by one under a given film forming condition (temperature, time and the like), the gases are adsorbed on an atom-layer basis, and films are formed utilizing surface reaction.

When a SiN (silicon nitride) film is to be formed for example, according to the ALD method, it is possible to form a high quality film at a low temperature in a range of 300 to 600° C. using DCS (SiH₂Cl₂, dichlorsilane) and NH₃ (ammonia) as chemical reaction to be utilized. A plurality of kinds of reaction gases are alternately supplied one by one. The film thickness is controlled based on the number of cycles of the supply of reaction gas. (When a film forming speed is 1 Å/cycle, in order to form a film of 20 Å, the film forming processing is carried out by 20 cycles.)

First, the boat 217 is charged with wafers 200 on which films are to be formed, and the boat 217 is loaded into the processing chamber 201. After the loading, the following four steps are executed sequentially.

(Step 1)

In step 1, NH₃ gas which needs plasma excitation and DCS gas which does not need plasma excitation flow in parallel.

First, the valve 243d of the gas exhaust tube 231 is opened to evacuate the processing chamber 201, NH₃ gas flows into the raw material gas supply tube 232a and in this state, the valve 243a of the raw material gas supply tube 232a is opened. The valve 404 of the gas exhaust tube 402 is kept closed during the film forming.

NH₃ gas, with the flow rate thereof being adjusted by the mass flow controller 241a, blows into the buffer chamber 237 from the gas supply holes 248b of the nozzle 233. In this state, high frequency electricity is applied between the rod-like electrodes 269 and 270 from the high frequency power supply 273 through the matching device 272 to plasma-excite NH₃ gas. The plasma-excited NH₃ gas is supplied into the processing chamber 201 as an active species, and the NH₃ gas is exhausted from the gas exhaust tube 231.

When the NH₃ gas flows as the active species by plasma excitation, the valve 243d is appropriately adjusted to maintain a pressure in the processing chamber 201 at a desired pressure within a range of 10 to 100 Pa. The supply flow rate of NH₃ gas is controlled by controlling the mass flow controller 241a to be a desired flow rate within a range of 1 to 10 slm. Time during which the wafers 200 are exposed to the active species obtained by plasma-exciting NH₃ is set to be a desired time within a range of 2 to 120 seconds. The temperature of the wafers 200 at this time is set to be a desired temperature within a range of 300 to 600° C. by controlling the heater 207. Since a reaction temperature of NH₃ gas is high, NH₃ gas does not react at the above-mentioned wafer temperature. Therefore, NH₃ flows as active species by plasma excitation in the present embodiment. Thus, the processing can be performed with the wafer temperature being set in the low temperature range.

When NH₃ is plasma-excited and supplied as active species, the valve 243b located at an upstream side of the raw material gas supply tube 232b is opened, the valve 243c located at a downstream side is closed to flow DCS gas also. With this, DCS is stored in the gas reservoir 247 provided between the valves 243b and 243c. At that time, gas flowing into the processing chamber 201 is an active species obtained by plasma-exciting NH₃ gas, and DCS gas does not exist in the processing chamber 201. Therefore, NH₃ gas which is plasma-excited and becomes active species surface-reacts with (chemisorb) a surface portion such as a underlying film on the wafer 200 without causing vapor-phase reaction.

(Step 2)

In step 2, the valve 243a of the raw material gas supply tube 232a is closed to stop the supply of NH₃ gas, but DCS gas is continued to flow to continue the supply of the DCS gas to the gas reservoir 247. When a predetermined amount of DCS at a predetermined pressure is stored in the gas reservoir 247, the upstream valve 243b is also closed to trap DCS in the gas reservoir 247. The valve 243d of the gas exhaust tube 231 is left open, the atmosphere in the processing chamber 201 is exhausted to 20 Pa or less by the vacuum pump 246, and NH₃ gas remained in the processing chamber 201 is exhausted from the processing chamber 201.

At this time, an inert gas such as K₂ may be supplied into the processing chamber 201, and the effect for eliminating NH₃ gas remained in the processing chamber 201 is further enhanced. DCS gas is stored in the gas reservoir 247 such that the pressure therein becomes 20000 Pa or higher. Further, the apparatus is constituted such that a conductance between the gas reservoir 247 and the processing chamber 201 becomes 1.5×10⁻³ m³/s or higher.

It is preferable that a capacity of the gas reservoir 247 is in a range of 100 to 300 cc if a capacity of the reaction tube 203 is 100 l (liters) when considering a ratio of a required capacity of the gas reservoir 247 to a capacity of the reaction tube 203, and that the capacity ratio of the gas reservoir 247 is 1/1000 to 3/1000 times of the reaction chamber capacity.

(Step 3)

In step 3, after exhausting the processing chamber 201, the valve 243d of the gas exhaust tube 231 is closed to stop exhausting. The valve 243c which is located at a downstream side of the raw material gas supply tube 232b is opened. With this, DCS gas stored in the gas reservoir 247 is supplied into the processing chamber 201 at a dash from the gas supply holes 246d of the nozzle 234 through the gas supply holes 248c. At this time, since the valve 243d of the gas exhaust tube 231 is closed, the pressure in the processing chamber 201 abruptly increases and reaches to about 931 Pa (7 Torr). Time during which DCS gas is supplied is set to two to four seconds, and time during which the wafers 200 are exposed to the increased pressure atmosphere thereafter is set to two to four seconds, and the total time is set to six seconds. The wafer temperature at this time is maintained at a desired temperature within a range of 300 to 600° C. like the case when NH₃ gas is supplied. By supplying DCS gas, DCS and NH₃ which have been chemisorbed on a surface of the wafer 200 surface-react (chemically react) with each other, and a SiN film is formed on a wafer 200.

(step 4)

In step 4 after the film formation, the valve 243c is closed, the valve 243d is opened to evacuate, and DCS gas remained in the processing chamber 201 after contributing to the film formation is eliminated.

At this time, an inert gas such as N₂ may be supplied into the processing chamber 201, and the effect for eliminating, from the processing chamber 201, DCS gas remained in the processing chamber 201 after contributing to the film formation is further enhanced. The valve 243b is opened to start the supply of DCS gas to the gas reservoir 247.

The above steps 1 to 4 are defined as one cycle. By repeating this cycle a plurality of times, a SiN film having a predetermined thickness is formed on the wafer 200.

In the ALD apparatus, gas is chemisorbed on a surface portion of the wafer 200. The absorption amount of gas is proportional to gas pressure and gas exposing time. Therefore, in order to absorb a desired given amount of gas within a short time, it is necessary to increase the pressure of gas within a short time. In this point, in the present embodiment, since the valve 243d is closed and DCS gas stored in the gas reservoir 247 is instantaneously supplied, it is possible to abruptly increase the pressure of DCS gas in the processing chamber 201, and to absorb a desired constant amount of gas instantaneously.

In the present embodiment, while DCS gas is stored in the gas reservoir 247, NH₃ gas is plasma-excited and supplied as an active species and exhausted from the processing chamber 201. This step of supplying the plasma-excited NH₃ gas is necessary in the ALD method. Therefore, a special step for storing DCS is not required. Further, since DCS gas flows after exhausting the inside of the processing chamber 201 to remove NH₃ gas, NH₃ gas and DCS gas do not react with each other on the way to the wafers 200. The supplied DCS gas can react effectively only with NH₃ gas absorbed on the wafers 200.

The above steps 1 to 4 are defined as one cycle, and this cycle is repeated a plurality of times and a SiN film having a predetermined film thickness is formed. When the film forming operation of the SiN film is carried out predetermined times, the processing chamber 201 is cleaned using cleaning gas. In the present embodiment, NF₃ gas is used as one example of the cleaning gas. The following two steps are mainly carried out in the cleaning processing.

(Step C1)

In step C1, NF₃ gas is charged into the processing chamber 201.

More specifically, the valve 243d of the gas exhaust tube 231 and the valve 404 of the gas exhaust tube 402 are opened, and in a state where the inside of the processing chamber 201 is exhausted (valves 243a and 243b are closed), the valves 304 and 354 are opened, the valves 308 and 243c are closed, NF₃ gas flows into the cleaning gas supply tubes 300 and 350, and NF₃ gas is retained in the gas reservoirs 306 and 247 while adjusting flow rates of the NF₃ gas by the mass flow controllers 302 and 352.

If a predetermined amount of NF₃ gas is retained in the gas reservoirs 306 and 247, the valves 304 and 354 are closed, the reserving operation of NF₃ gas in the gas reservoirs 306 and 247 is stopped, and the valves 243d and 404 are also closed. In this state, the valves 308 and 243c are opened, and NF₃ gas retained in the gas reservoirs 306 and 247 is supplied (flash flow) to the processing chamber 201 at a dash.

In this case, NF₃ gas retained in the gas reservoir 247 is injected into the processing chamber 201 from the gas supply hole 248c through the gas supply holes 248d after passing through the gas supply tube 232b and the nozzle 234. On the other hand, NF₃ gas retained in the gas reservoir 306 passes through the cleaning gas supply tube 300 and is injected into the processing chamber 201 from the short tube 301. That is, in the processing in step C1, NF₃ gas as the cleaning gas is supplied to the processing chamber 201 from both the nozzle 234 and the short tube 301 at the same time.

If NF₃ gas is supplied to the processing chamber 201 from both the nozzle 234 and short tube 301 in this manner, it is possible to prevent or suppress a dead space caused by a structure in the processing chamber 201 or a flow velocity of NF₃ gas from being generated as compared with a case where the substrate processing apparatus does not have this structure.

If predetermined time is elapsed after the valves 308 and 243c are opened, the procedure is shifted to processing of step C2.

(Step C2)

In step C2, gas that has filled the processing chamber 201 is exhausted from the processing chamber 201. In the processing chamber 201, a SiN film (unnecessary SiN film to be removed) accumulated in the processing chamber 201 by the film forming processing reacts with NF₃ gas supplied in step C1, and as a result of the reaction, mainly SiF₄ gas and N₂ gas fill the processing chamber 201 (including non-reacted NF₃ gas). These gases are exhausted from the processing chamber 201.

More specifically, the valve 243d of the gas exhaust tube 231 and the valve 404 of the gas exhaust tube 402 are opened, and gas that has filled the processing chamber 201 is exhausted at a dash through the gas exhaust tubes 231 and 402. At that time, since conductance (flowing easiness of gas) of the gas exhaust tube 231 and conductance of the gas exhaust tube 402 are different, if a pressure variation in the processing chamber 201 is extremely large (e.g., when pressure of 10 Torr or higher is instantaneously reduced to 0.1 Torr or lower), only the valve 404 may be opened to exhaust gas. On the other hand, when the pressure variation in the processing chamber 201 is not so serious (e.g., when pressure less than 10 Torr is reduced to about 0.1 Torr), only the valve 243d may be opened to exhaust gas.

If a predetermined time is elapsed after the valves 243d and 404 are opened, the processing in step C2 is completed. Thereafter, steps C1 and C2 are defined as one cycle, this cycle is repeated predetermined times, and the cleaning of the processing chamber 201 is completed.

It is also possible to store NF₃ gas into the gas reservoirs 306 and 247 (that is, to perform processing of opening the valves 304 and 354, closing the valves 308 and 243c to store NF₃ gas into the gas reservoirs 306 and 247) simultaneously with carrying out the processing in step C2. In this case, the processing time in the entire cleaning step can be shortened.

In this embodiment, when the inside of the processing chamber 201 is cleaned, NF₃ gas which has been temporality stored in the gas reservoirs 306 and 247 in step C1 is supplied to the processing chamber 201 for NF₃ gas to react with SiN film, and SiF₄ gas, N₂ gas and the like generated by this reaction are exhausted from the processing chamber 201 in step C2. These operations repeatedly carried out. Therefore, abrupt pressure variation is generated in the processing chamber 201, and SiN films accumulated in the processing chamber 201 can sufficiently be removed.

Especially in step C1, NF₃ gas is supplied to the processing chamber 201 from both the gas supply holes 248c of the gas supply section 249 and the short tube 301 of the cleaning gas supply tube 300 in a state where exhausting valves 243d and 404 are closed. Therefore, NF₃ gas flows into the processing chamber 201 at a dash. Thus, even if there exists a region where gas can not flow easily in the processing chamber 201, NF₃ gas positively flows into that region, and it is possible to prevent or suppress a dead space from being generated in the processing chamber 201. Thus, NF₃ gas and a SiN film accumulated in a region where the gas can not flow easily can forcibly be brought into contact with each other, and the SiN film accumulated in the processing chamber 201 can sufficiently be removed.

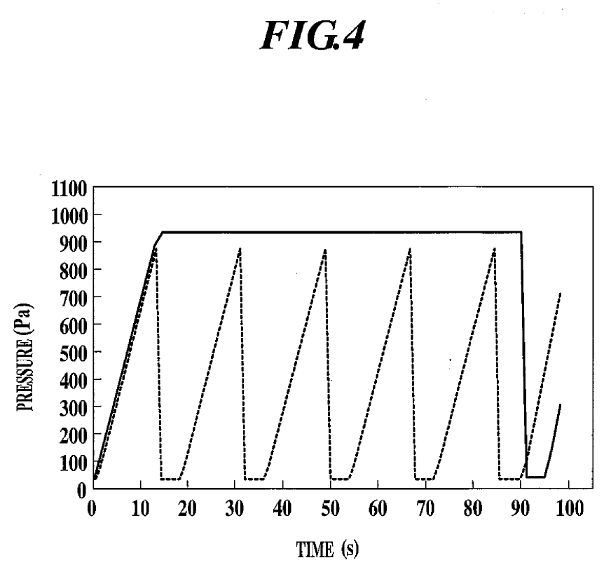

If the exhaust valves 243d and 404 are closed and cleaning gas is instantaneously supplied, the following effects can be obtained. That is, since the cleaning gas is supplied when there is no wafer 200 in the processing chamber 201, the gas supply efficiency can be enhanced. Further, in FIG. 4, time x pressure becomes equal to an area of a lower portion of the graph, and since this area corresponds to a gas supply amount, if the supply operation and the exhaust operation of cleaning gas are alternately carried out, the cleaning operation can be carried out with a smaller gas supply amount.

Further, since NF₃ gas supplied from the cleaning gas supply tubes 300 and 350 are stored in the gas reservoirs 306 and 247, a gas pressure of the cleaning gas stored in the gas reservoirs 306 and 247 can be increased. Thereafter, the valves 308 and 243c are opened in a state where the exhaust valves 243d and 404 are closed, and NF₃ gas stored in the gas reservoirs 306 and 247 is supplied to the processing chamber 201 at a dash. Therefore, as compared with a case where there are no gas reservoirs 306 and 247, it is possible to more effectively prevent or suppress a dead space from being generated in the processing chamber 201.

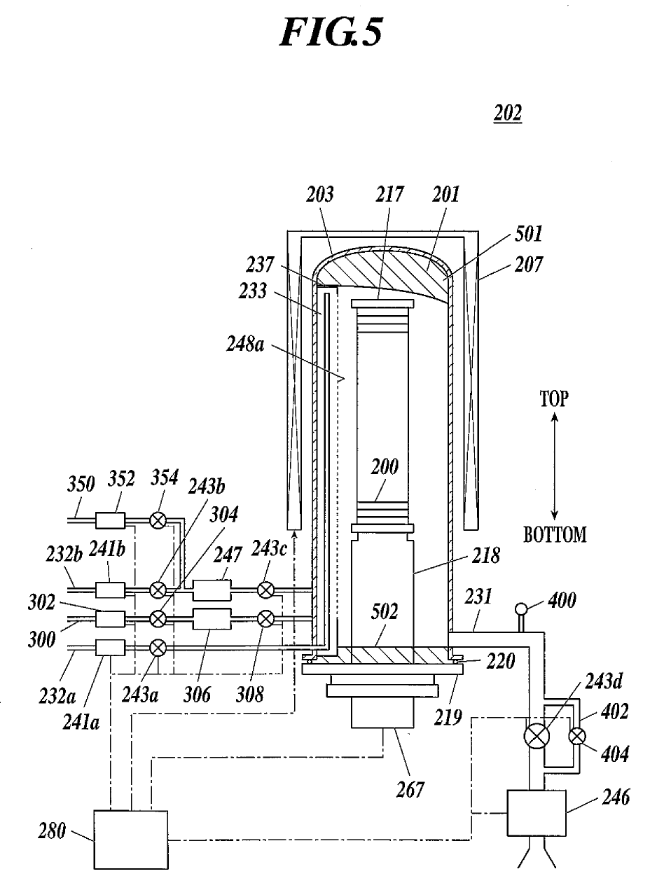

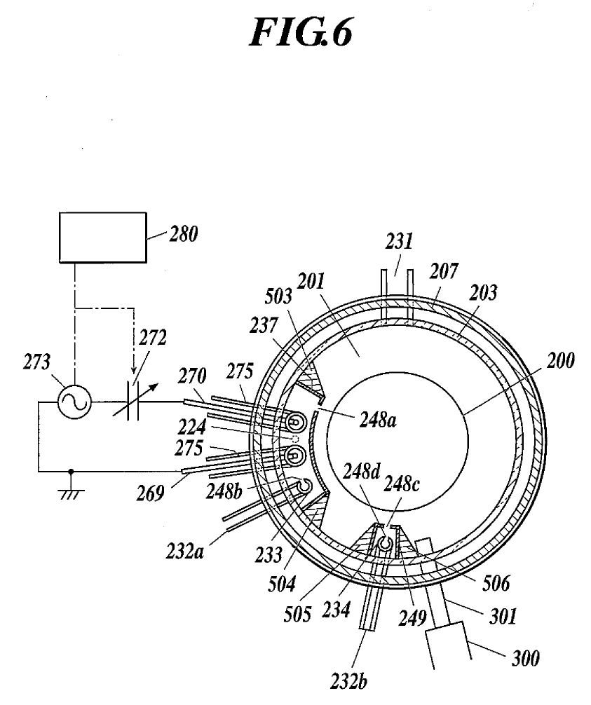

Dead spaces where gas cannot flow easily are an upper portion and a lower portion in the processing chamber, and are portions 501 to 505 shown in FIGS. 5 and 6.

In addition to the above facts, in step C1 since NF₃ gas is supplied to the processing chamber 201 from the gas supply tube 232b, NF₃ gas flows through the nozzle 234, and a polycrystalline Si film formed when the SiN film is formed can also be removed from the nozzle 234.

By supplying NF₃ gas to the processing chamber 201 from the cleaning gas supply tube 300, the NF₃ gas is injected into the lower region in the processing chamber 201, and foreign matter accumulated in the lower region (or foreign matter which is prone to be accumulated) can also be removed. Especially, the inner diameter of the short tube 301 becomes small as small as about ½ of an inner diameter of the cleaning gas supply tube 300 regarding the cleaning gas supply tube 300 and the short tube 301 connected to the cleaning gas supply tube 300. Therefore, as compared with a case where the cleaning gas supply tube 300 is simply brought into communication with the processing chamber 201, a pressure of the cleaning gas is increased (flow velocity is increased), and a removing effect of foreign matter is enhanced. One of reason why the cleaning gas supplying short tube 301 is provided in the lower region in the processing chamber 201 is that the cleaning effect becomes weaker in the lower portion in the processing chamber 201 and therefore it is desired to strengthen the cleaning effect in the lower portion. Here, the lower portion in the processing chamber 201 is a portion therein lower than the heater 207.

Although NF₃ gas is supplied to the processing chamber 201 from the cleaning gas supply tube 300 and the gas supply tube 232b in the present embodiment, the NF₃ gas may be supplied only from the cleaning gas supply tube 300 or the gas supply tube 232b.

A pressure in the processing chamber 201 when cleaning gas is not supplied to the processing chamber 201 is controlled to a vacuum pressure. A pressure difference in the processing chamber 201 before and after the cleaning gas is supplied is set to 7 to 400 Torr, more preferably to 7 to 30 Torr. This is because that if the pressure is excessively increased, gas must be exhausted after the cleaning gas is supplied and thus, the efficiency is deteriorated.

A film adhered to the processing chamber 201 is peeled off easier as the film density is higher. Therefore, the cleaning frequency varies depending upon the kinds of film. For example, in the case of a SiN film adhered to the inner wall of the processing chamber 201 made of quartz (SiO₂), it is preferable that the cleaning operation is carried out every 100 RUNs (2 μm) to 250 RUNs (5 μm), and more preferably, every 100 RUNs (2 μm). Here, 1 RUN means a process in which a predetermined number of wafers 200 are inserted into the processing chamber 201, a film forming operation on the wafers 200 is carried out once and then, the wafers 200 are taken out from the processing chamber 201, and 100 RUNs mean that this process is carried out 100 times.

Although NF₃ is used as the cleaning gas in this embodiment, halogen-based (group 17) gas such as F₂, HF, ClF₃ and BCl₃ can also be used.

The process condition varies depending upon the kinds of cleaning gas, and it is preferable that the cleaning temperature is 630° C. in the case of NF₃, and 350° C. in the case of F₂.

A processing temperature when raw material gas is used and a processing temperature when cleaning gas is used need not be the same, and even if a film forming temperature is in a range of 550 to 630° C., the cleaning temperature may be 630° C. when NF₃ is used, and may be 350° C. when F₂ is used.

Although NF₃ gas as cleaning gas is supplied to the processing chamber 201 from both the nozzle 234 and the short tube 301 at the lower portion of the processing chamber, different kinds of cleaning gases can be supplied from the nozzle 234 and from the short tube 301. For example, NF₃ may be supplied from the nozzle 234 and F₂ having a low processing temperature may be supplied from the short tube 301.

If cleaning gases are supplied substantially simultaneously to the processing chamber 201 from both the nozzle 234 and the short tube 301 of the lower portion of the processing chamber, it is possible to prevent cross contamination (interference) between the nozzle 234 and the short tube 301. That is, if gas is supplied from only one of the nozzle 234 and the short tube 301, this gas enters into the other one, but if the gases flow through at the same time, it is possible to prevent the gas from entering the other one.

A thickness of the nozzle 234 is thin, and if the nozzle 234 is etched using etching gas such as NF₃, the strength of the nozzle 234 is deteriorated. Thus, if inert gas such as N₂ pushes the etching gas after the etching gas is supplied, it is possible to reduce the damage of the nozzle itself.

Since the exhausting valves 243d and 404 are completely closed when cleaning gas is supplied, it is unnecessary to control the pressure in the processing chamber 201. If the exhausting valves 243d and 404 are opened even slightly, this means that the cleaning gas is thrown out and thus, these valves should not be opened. If these valves 243d and 404 are completely closed on the other hand, the flowing direction of the gas is changed and the processing chamber 201 is filled with the cleaning gas and thus, there is an effect that a dead space is eliminated.

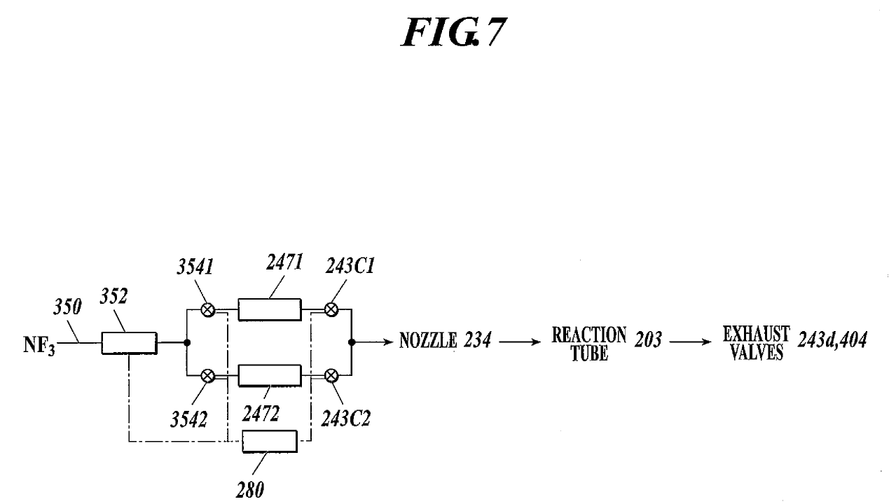

In order to increase the amount of gas which is supplied to the processing chamber at a time, it is more efficient if a plurality of gas reservoirs are provided in one gas supply line in parallel as compared with a case one gas reservoir having a large capacity is provided. This is because while cleaning gas is supplied to the processing chamber 201 from one of the gas reservoirs, cleaning gas can be stored in the remaining gas reservoirs and thus, time during which cleaning gas is stored in the gas reservoir can be saved. Further, if the plurality of reservoirs are provided, it is possible to make the flow rate control of the cleaning gas mass flow controller constant, as shown in FIG. 7. This constant flow rate control allows a flow controller, for example, a mass flow meter (MFM) to be used which has only a flow rate monitor and has no flow rate control function.

FIG. 7 shows an example of a case where two gas reservoirs 2471 and 2472 are provided instead of the gas reservoir 247. Valves 3541 and 243c1 are respectively provided upstream and downstream of the gas reservoir 2471, and valves 3542 and 243c2 are respectively provided upstream and downstream of the gas reservoir 2472. The valve 3541, 3542, 243c1 and 243c2 are connected to a controller 280, and opening and closing operations of the valve 3541, 3542, 243c1 and 243c2 are controlled by the controller 280.

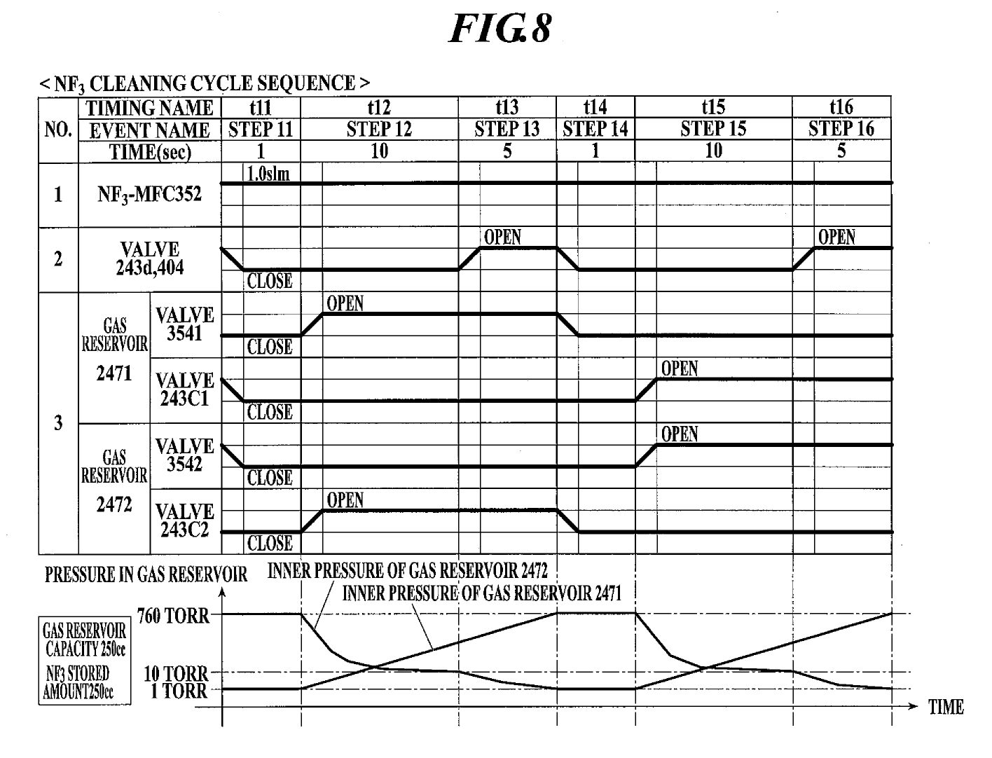

FIG. 8 is a sequence diagram when these two gas reservoirs 2471 and 2472 are used.

A flow rate of the mass flow controller 352 which flows NF₃ gas is constant and is 1.0 slm from steps 11 to 16.

In step 11, the valve 243d of the gas exhaust tube 231 and the valve 404 of the gas exhaust tube 402 are closed, and the exhaustion of the inside of the processing chamber 201 is stopped. The valve 3541 upstream of the gas reservoir 2471 is kept closed, the downstream valve 243c1 is closed, and the supply of NF₃ gas stored in the gas reservoir 2471 to the processing chamber 201 is stopped. The valve 243c2 downstream of the gas reservoir 2472 is kept closed, the upstream valve 3542 is closed, and accumulation of NF₃ gas in the gas reservoir 2471 is stopped.

In step 12, the valves 243d and 404 are closed, and in a state where the exhaustion of the inside of the processing chamber 201 is stopped, the valve 243c2 downstream of the gas reservoir 2472 is opened, and NF₃ gas stored in the gas reservoir 2472 is supplied to the processing chamber 201 at a dash.

In step 13, in a state where the valve 243c2 downstream of the gas reservoir 2472 is opened, the valve 243d of the gas exhaust tube 231 and the valve 404 of the gas exhaust tube 402 are opened so that the inside of the processing chamber 201 is exhausted while supplying NF₃ gas from the gas reservoir 2472 to the processing chamber 201.

While carrying out the steps 12 and 13, the valve 243c1 downstream of the gas reservoir 2471 is kept closed and the valve 3541 upstream of the gas reservoir 2471 is opened to store NF₃ gas in the gas reservoir 2471.

In step 14, the valve 243d of the gas exhaust tube 231 and the valve 404 of the gas exhaust tube 402 are closed, and the exhaustion of the inside of the processing chamber 201 is stopped. The valve 3542 upstream of the gas reservoir 2472 is kept closed, the downstream valve 243c2 is closed, and the supply of NF₃ gas stored in the gas reservoir 2472 to the processing chamber 201 is stopped. The valve 243c1 downstream of the gas reservoir 2471 is kept closed, the upstream valve 3541 is closed, and accumulation of NF₃ gas in the gas reservoir 2471 is stopped.

In step 15, the valves 243d and 404 are closed, and in a state where the exhaustion of the inside of the processing chamber 201 is stopped, the valve 243c1 downstream of the gas reservoir 2471 is opened, and NF₃ gas stored in the gas reservoir 2471 is supplied to the processing chamber 201 at a dash.

In step 16, in a state where the valve 243c1 downstream of the gas reservoir 2471 is opened, the valve 243d of the gas exhaust tube 231 and the valve 404 of the gas exhaust tube 402 are opened so that the inside of the processing chamber 201 is exhausted while supplying NF₃ gas from the gas reservoir 2471 to the processing chamber 201.

While carrying out the steps 15 and 16, the valve 243c2 downstream of the gas reservoir 2472 is kept closed and the upstream valve 3542 is opened to store NF₃ gas in the gas reservoir 2472.

The above steps 11 to 16 are defined as one cycle, and this cycle is repeated a plurality of times to perform the cleaning of the processing chamber 201.

For example, if the capacities of the gas reservoirs 2471 and 2472 are respectively 250 cc, the pressure of NF₃ gas supplied from the cleaning gas supply tube 350 is 760 Torr, the amounts of NF₃ gas stored in the gas reservoirs 2471 and 2472 are respectively 250 cc, the pressure of the inside of the gas reservoirs 2472 lowers from 760 Torr to 10 Torr in step 12, and from 10 Torr to 1 Torr in step 13. The pressure of the inside of the gas reservoirs 2471 rises from 1 Torr to 760 Torr in steps 12 and 13. The pressure of the inside of the gas reservoirs 2471 remains 760 Torr in steps 14, and lowers from 760 Torr to 10 Torr in step 15, and from 10 Torr to 1 Torr in step 16. The pressure of the inside of the gas reservoirs 2472 remains 10 Torr in steps 14, and rises from 1 Torr to 760 Torr in steps 15 and 16.

In step 13, the valve 243c2 downstream of the gas reservoir 2472, the valve 243d of the gas exhaust tube 231 and the valve 404 of the gas exhaust tube 402 are opened. In step 16, the valve 243c1 downstream of the gas reservoir 2471, the valve 243d of the gas exhaust tube 231 and the valve 404 of the gas exhaust tube 402 are opened. The purpose of this is that amounts of cleaning gases to be charged into the gas reservoir 2471 and the gas reservoir 2472 become equal to each other every cycle. If the above procedure is not adopted, influence of cleaning gas remaining in the gas reservoirs 2471 and 2472 is received, and the amounts of cleaning gases to be charged into the gas reservoirs 2471 and 2472 become different from each other every cycle.

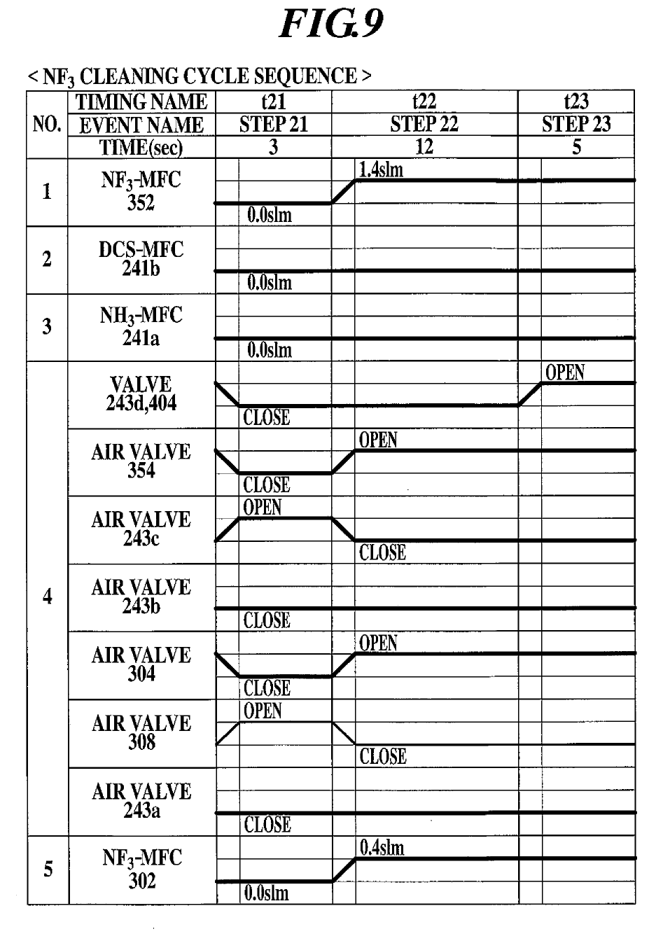

FIG. 9 is a sequence diagram for explaining a case where NF₃ gas as a cleaning gas is supplied from both the nozzle 234 and the short tube 301, and the gas reservoirs 247 and 306 are used.

From step 21 to step 23, a flow rate of the mass flow controller 241b which flows DCS gas and a flow rate of the mass flow controller 241a which flows NF₃ gas are 0.0 slm. The valve 243b upstream of the gas reservoir 247 of the raw gas supply tube 232b and the valve 243a of the raw gas supply tube 232a are kept closed.

In step 21, a flow rate of the mass flow controller 352 which flows NF₃ gas to the cleaning gas supply tube 350 is 0.0 slm, the valve 354 upstream of the gas reservoir 247 is closed, and the accumulation of NF₃ gas in the gas reservoir 247 is stopped. A flow rate of the mass flow controller 302 which flows NF₃ gas to the cleaning gas supply tube 300 is 0.0 slm, the valve 304 upstream of the gas reservoir 306 is closed, and the accumulation of NF₃ gas in the gas reservoir 306 is stopped. The valve 243d of the gas exhaust tube 231 and the valve 404 of the gas exhaust tube 402 are closed, and the exhaustion of the inside of the processing chamber 201 is stopped.

Thereafter, in a state where the exhaustion of the inside of the processing chamber 201 is stopped, the valve 243c downstream of the gas reservoir 247 is opened, and NF₃ gas stored in the gas reservoir 247 is supplied from the nozzle 234 to the processing chamber 201 at a dash, and the valve 308 downstream of the gas reservoir 306 is opened, and NF₃ gas stored in the gas reservoir 306 is supplied from the short tube 301 to the processing chamber 201 at a dash.

In step 22, the valve 243d of the gas exhaust tube 231 and the valve 404 of the gas exhaust tube 402 are closed, and the exhaustion of the inside of the processing chamber 201 is kept stopped. A flow rate of the mass flow controller 352 is set to be 1.4 slm, the valve 243c downstream of the gas reservoir 247 is closed and the upstream valve 354 is opened to store NF₃ gas in the gas reservoir 247. A flow rate of the mass flow controller 302 is set to be 1.4 slm, the valve 308 downstream of the gas reservoir 306 is closed and the upstream valve 304 is opened to store NF₃ gas in the gas reservoir 306.

In step 23, the valve 243d of the gas exhaust tube 231 and the valve 404 of the gas exhaust tube 402 are opened so that the inside of the processing chamber 201 is exhausted.

The above steps 21 to 23 are defined as one cycle, and this cycle is repeated a plurality of times to perform the cleaning of the processing chamber 201.

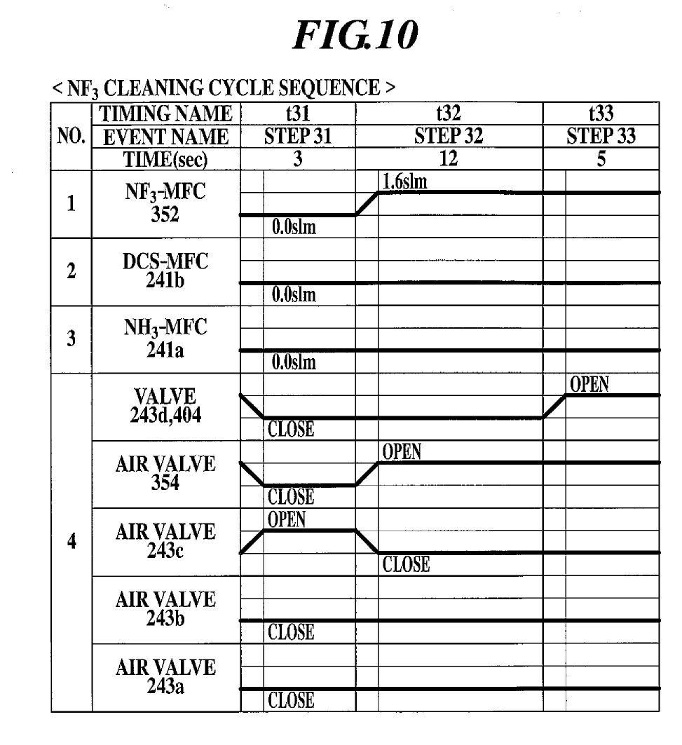

FIG. 10 is a sequence diagram for explaining a case where NF₃ gas as a cleaning gas is supplied only from the nozzle 234, and only the gas reservoir 247 is used;

From step 31 to step 33, a flow rate of the mass flow controller 241b which flows DCS gas and a flow rate of the mass flow controller 241a which flows NF₃ gas are 0.0 slm. The valve 243b upstream of the gas reservoir 247 of the raw gas supply tube 232b and the valve 243a of the raw gas supply tube 232a are kept closed.

In step 31, a flow rate of the mass flow controller 352 which flows NF₃ gas to the cleaning gas supply tube 350 is 0.0 slm, the valve 354 upstream of the gas reservoir 247 is closed, and the accumulation of NF₃ gas in the gas reservoir 247 is stopped. The valve 243d of the gas exhaust tube 231 and the valve 404 of the gas exhaust tube 402 are closed, and the exhaustion of the inside of the processing chamber 201 is stopped.

Thereafter, in a state where the exhaustion of the inside of the processing chamber 201 is stopped, the valve 243c downstream of the gas reservoir 247 is opened, and NF₃ gas stored in the gas reservoir 247 is supplied from the nozzle 234 to the processing chamber 201 at a dash.

In step 32, the valve 243d of the gas exhaust tube 231 and the valve 404 of the gas exhaust tube 402 are closed, and the exhaustion of the inside of the processing chamber 201 is kept stopped. A flow rate of the mass flow controller 352 is set to be 1.6 slm, the valve 243c downstream of the gas reservoir 247 is closed and the upstream valve 354 is opened to store NF₃ gas in the gas reservoir 247.

In step 33, the valve 243d of the gas exhaust tube 231 and the valve 404 of the gas exhaust tube 402 are opened so that the inside of the processing chamber 201 is exhausted.

The above steps 31 to 33 are defined as one cycle, and this cycle is repeated a plurality of times to perform the cleaning of the processing chamber 201.

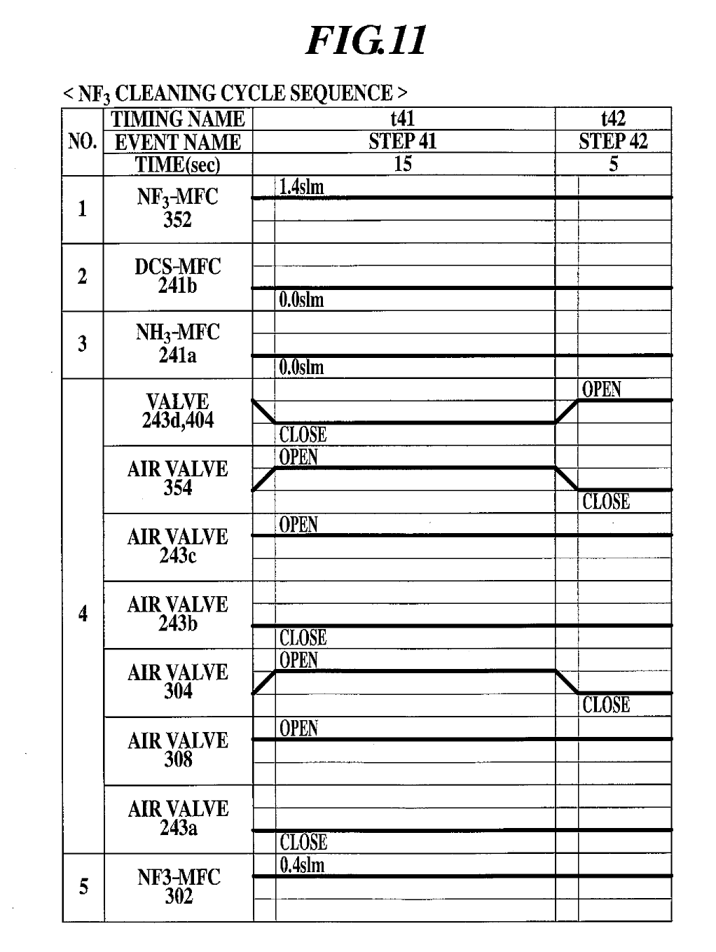

FIG. 11 is a sequence diagram for explaining a case where NF₃ gas as a cleaning gas is supplied from both the nozzle 234 the short tube 301, and the gas reservoirs 247 and 306 are not used.

From step 41 to step 42, a flow rate of the mass flow controller 241b which flows DCS gas and a flow rate of the mass flow controller 241a which flows NF₃ gas are 0.0 slm. The valve 243b upstream of the gas reservoir 247 of the raw gas supply tube 232b and the valve 243a of the raw gas supply tube 232a are kept closed. A flow rate of the mass flow controller 352 which flows NF₃ gas to the cleaning gas supply tube 350 is 1.4 slm, and a flow rate of the mass flow controller 302 which flows NF₃ gas to the cleaning gas supply tube 300 is 0.4 slm. The valve 243c downstream of the gas reservoir 247 and the valve 308 downstream of the gas reservoir 306 are kept open.

In step 41, the valve 243d of the gas exhaust tube 231 and the valve 404 of the gas exhaust tube 402 are closed, and the exhaustion of the inside of the processing chamber 201 is stopped. In a state where the exhaustion of the inside of the processing chamber 201 is stopped, the valve 354 upstream of the gas reservoir 247 of the cleaning gas supply tube 350 is opened, and NF₃ gas is supplied from the nozzle 234 to the processing chamber 201, and the valve 304 upstream of the gas reservoir 306 of the cleaning gas supply tube 350 is opened, and NF₃ gas is supplied from the short tube 301 to the processing chamber 201.

In step 42, the valve 354 of the cleaning gas supply tube 350 and the valve 304 of the cleaning gas supply tube 350 closed, and the valve 243d of the gas exhaust tube 231 and the valve 404 of the gas exhaust tube 402 are opened so that the inside of the processing chamber 201 is exhausted.

The above steps 41 to 42 are defined as one cycle, and this cycle is repeated a plurality of times to perform the cleaning of the processing chamber 201.

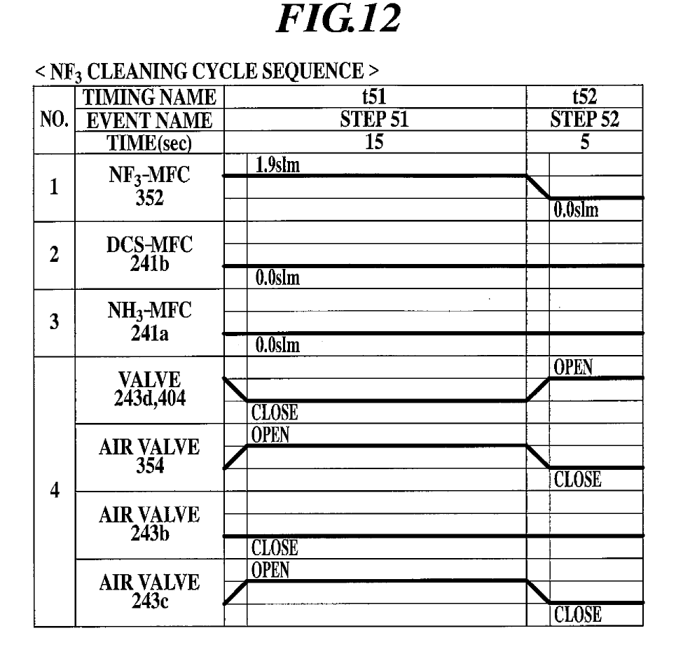

FIG. 12 is a sequence diagram for explaining a case where NF₃ gas as a cleaning gas is supplied only from the nozzle 234, and the gas reservoir 247 is not used.

From step 51 to step 52, a flow rate of the mass flow controller 241b which flows DCS gas and a flow rate of the mass flow controller 241a which flows NF₃ gas are 0.0 slm. The valve 243b upstream of the gas reservoir 247 of the raw gas supply tube 232b is kept closed.

In step 51, the valve 243d of the gas exhaust tube 231 and the valve 404 of the gas exhaust tube 402 are closed, and the exhaustion of the inside of the processing chamber 201 is stopped. A flow rate of the mass flow controller 302 which flows NF₃ gas to the cleaning gas supply tube is 1.9 slm. In a state where the exhaustion of the inside of the processing chamber 201 is stopped, the valve 354 upstream of the gas reservoir 247 and the valve 243c downstream of the same are opened, and NF₃ gas is supplied from the nozzle 234 to the processing chamber 201.

In step 52, a flow rate of the mass flow controller 352 is made 0.0 slm, and the valve 354 upstream of the gas reservoir 247 and the valve 243c downstream of the same are closed and the valve 243d of the gas exhaust tube 231 and the valve 404 of the gas exhaust tube 402 are opened so that the inside of the processing chamber 201 is exhausted.

The above steps 51 to 52 are defined as one cycle, and this cycle is repeated a plurality of times to perform the cleaning of the processing chamber 201.

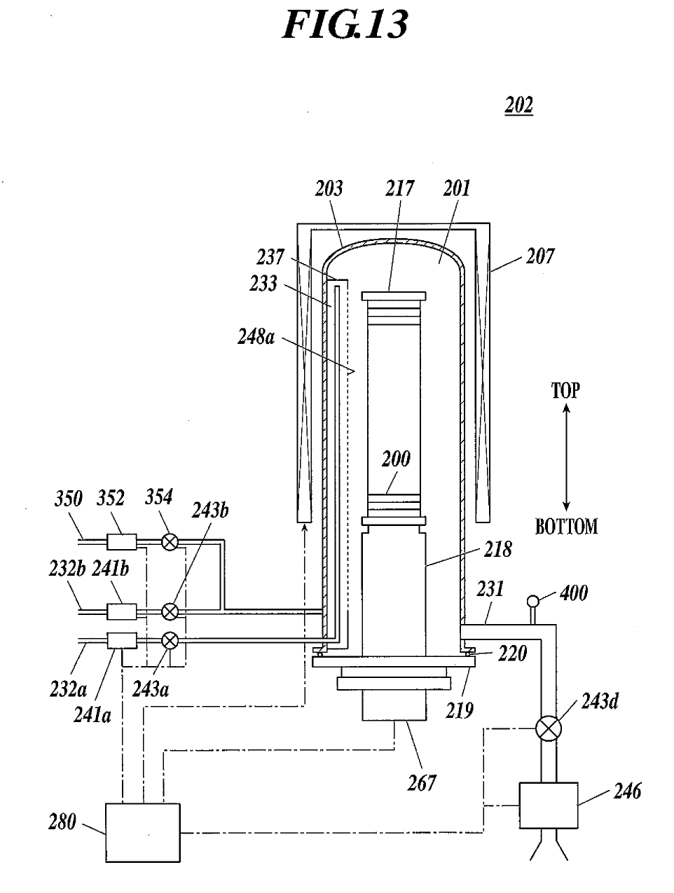

Here, a structure shown in FIG. 13 as a comparative example of a structure of the present embodiment can be assumed. The structure of the comparative example does not have the cleaning gas supply tube 300 and members coming with the cleaning gas supply tube 300 (the mass flow controller 302, the valve 304, the gas reservoir 306 and the valve 308), the gas reservoir 247, the valve 243c, the gas exhaust tube 402 and the valve 404. The cleaning gas supply tube 350 is connected to the raw material gas supply tube 232b at a location downstream from the valve 243b.

When the processing chamber 201 is cleaned with the structure of this comparative example, a flow rate of the mass flow controller 352 and an opening degree of the valve 243d are adjusted using the mass flow controller 352, the vacuum gage 400 and the valve 243d, a pressure in the processing chamber 201 is controlled and in this state, NF₃ gas is supplied to the processing chamber 201 from the cleaning gas supply tube 350. If predetermined time is elapsed after the supply of NF₃ gas is started, the valve 354 is closed, the supply of NF₃ gas is stopped and the cleaning operation of the processing chamber 201 is completed.

According to the structure of the comparative example, the pressure in the processing chamber 201 is increased as the supply of NF₃ gas is started and thereafter, the pressure is maintained at a constant value and finally, the pressure is reduced as the supply of the NF₃ gas is stopped. In this case, since the pressure value is constant while the pressure in the processing chamber 201 is maintained at the constant value, there is a possibility that an unnecessary SiN film which is not peeled off at that pressure value remains in the processing chamber 201 as it is. Further, a constant gas flowing path is secured in the processing chamber 201, a dead space where gas can not flow easily is formed and a possibility that a SiN film remains in the dead space is high.

On the other hand, according to the structure of the above-mentioned embodiment in which steps C1 and C2 are repeated, as shown with a dotted line in FIG. 4, the pressure in the processing chamber 201 is increased as the NF₃ gas is supplied in step C1 and the pressure is reduced as the NF₃ gas is exhausted in step C2, and these pressure changes are repeated. Thus, according to the structure of the present embodiment, unlike the structure of the comparative example, time period during which the pressure value in the processing chamber 201 is maintained at a constant value does not exist at all or almost at all, or on the contrary, a pressure in the processing chamber 201 is varied. Therefore, a possibility that an unnecessary SiN film which is not peeled off even if the pressure value in the processing chamber 201 becomes maximum receives the pressure variation and is exhausted from the processing chamber 201 is high.

In the structure of the present embodiment, as described above, the time period during which the pressure value in the processing chamber 201 is maintained at a constant value does not exist at all or almost at all. Therefore, it is not easily conceived that the constant gas flowing path is secured in the processing chamber 201 and that a dead space where gas can not flow easily is formed. From the above reason, according to the structure of the present embodiment, it is possible to sufficiently remove SiN films accumulated in the processing chamber 211 including SiN films in a region where gas can not flow easily.

The result shown in FIG. 4 is obtained when the pressure in the processing chamber 201 is within 10 Torr using the pressure gage, and the result shown with dotted lines in FIG. 4 is obtained without using the gas exhaust tube 402 and the valve 404.

The entire disclosures of Japanese Patent Application Nos. 2007-170454 filed on Jun. 28, 2007 and 2008-160058 filed on Jun. 9, 2008 each including description, claims, drawings, and abstract are incorporated herein by reference in there entireties.

Although various exemplary embodiments have been shown and described, the invention is not limited to the embodiments shown. Therefore, the scope of the invention is intended to be limited solely by the scope of the claims that follow.

What is claimed is:

1. A substrate processing apparatus, comprising:
a processing chamber to process a substrate;
an exhaust path to exhaust the processing chamber;
an exhaust device to exhaust atmosphere in the processing chamber through the exhaust path;
an exhaust valve to open and close the exhaust path;
a raw material gas supply member to supply raw material gas which contributes to film forming into the processing chamber;
a cleaning gas supply member to supply cleaning gas which removes an accretion, which adheres to an inside of the processing chamber with the raw material gas being supplied, the cleaning gas supply member comprising a supply path to supply the cleaning gas to the processing chamber and a gas supply valve to open and close the supply path; and
a control section which controls the exhaust valve and the gas supply valve to supply the cleaning gas from the supply path to the processing chamber with exhaustion of the processing chamber being stopped.

2. A substrate processing apparatus as recited in claim 1, wherein
the raw material gas supply member comprises:
a second supply path to supply a first raw material gas of the raw material gas; and
a second gas supply valve to open and close the second supply path, the second supply path communicating with the first supply path at a downstream side of the first gas supply valve.

3. A substrate processing apparatus as recited in claim 2, wherein
the raw material gas supply member further comprises:
a third supply path to supply a second raw material gas of the raw material gas to the processing chamber, the second raw material gas being different from the first raw material gas; and
a third gas supply valve to open and close the third supply path, and
the control section controls the exhaust valve, the second gas supply valve and the third gas supply valve to repeat alternative supply of the first raw material gas and the second raw material gas to the processing chamber.

4. A substrate processing apparatus as recited in claim 1, wherein
the supply path comprises a gas reservoir disposed downstream of the first gas supply valve to store the cleaning gas and a second gas supply valve disposed downstream of the gas reservoir, and
the control section controls, when the cleaning gas is supplied to the processing chamber, the exhaust valve, the first gas supply valve and the second gas supply valve to supply the cleaning gas to the supply path to store the cleaning gas in the gas reservoir and to supply the cleaning gas stored in the gas reservoir to the processing chamber from the gas reservoir in a state in which exhaustion of the processing chamber being stopped.

5. A substrate processing apparatus as recited in claim 4, wherein
the control section controls, when the cleaning gas is supplied to the processing chamber, the exhaust valve, the first gas supply valve and the second gas supply valve to repeat storing the cleaning gas in the gas reservoir and supplying the cleaning gas stored in the gas reservoir to the processing chamber predetermined times.

6. A substrate processing apparatus, comprising:
a processing chamber to process a substrate;
a heating member disposed outside the processing chamber to heat an inside of the processing chamber;
an exhaust path to exhaust the processing chamber;
an exhaust device to exhaust atmosphere in the processing chamber through the exhaust path;
an exhaust valve to open and close the exhaust path;
a raw material gas supply member to supply raw material gas which contributes to film forming into the processing chamber;
a cleaning gas supply member to supply cleaning gas which removes an accretion, which adheres to an inside of the processing chamber with the raw material gas being supplied; and
a control section, wherein
the cleaning gas supply member comprises:
a first supply path to supply the cleaning gas to the processing chamber;
a first gas supply valve to open and close the first supply path;
a second supply path communicating with a lower portion of the processing chamber at a position lower than the heating member to supply the cleaning gas to the processing chamber; and
a second gas supply valve to open and close the second supply path,
the raw material gas supply member comprises:
a third supply path connected with the first supply path at a downstream side of the first gas supply valve to supply a first raw material gas of the raw material gas;
a third gas supply valve to open and close the third supply path;
a fourth supply path to supply a second raw material gas of the raw material gas to the processing chamber;
the second raw material gas being different from the first raw material gas; and
a fourth gas supply valve to open and close the fourth supply path, and
the control section controls the exhaust valve, the third gas supply valve and the fourth gas supply valve to alternatively supply the first raw material gas and the second raw material gas when the first raw material gas and the second raw material gas are supplied to form a desired film on the substrate, and
the control section controls the exhaust valve, the first gas supply valve and the second gas supply valve to supply the cleaning gas from the first supply path and the second supply path to the processing chamber with exhaustion of the processing chamber being stopped when the cleaning gas is supplied.

7. A substrate processing apparatus as recited in claim 6, wherein
the control section controls the first gas supply valve and the second gas supply valve to supply the cleaning gas simultaneously from the first supply path and the second supply path to the processing chamber when the cleaning gas is supplied.

8. A substrate processing apparatus as recited in claim 6, wherein
the first supply path further comprises a first gas reservoir to store the cleaning gas and a fifth gas supply valve disposed downstream of the first gas reservoir,
the second supply path further comprises a second gas reservoir to store the cleaning gas and a sixth gas supply valve disposed downstream of the second gas reservoir, and
the control section controls, when the cleaning gas is supplied to the processing chamber, the exhaust valve, the first gas supply valve, the second gas supply valve, the fifth gas supply valve and the sixth gas supply valve to supply the cleaning gas to the first supply path and the second supply path to store the cleaning gas in the first gas reservoir and the second gas reservoir and to supply the cleaning gas stored in the first gas reservoir and the second gas reservoir to the processing chamber from the first gas reservoir and the second gas reservoir in a state in which exhaustion of the processing chamber being stopped.

9. A substrate processing apparatus as recited in claim 8, wherein
the control section controls, when the cleaning gas is supplied to the processing chamber, the exhaust valve, the first gas supply valve, the second gas supply valve, the fifth gas supply valve and the sixth gas supply valve to repeat storing the cleaning gas in the first gas reservoir and the second gas reservoir and supplying the cleaning gas stored in the first gas reservoir and the second gas reservoir to the processing chamber predetermined times.

10. A substrate processing apparatus as recited in claim 1, wherein
a pressure difference in the processing chamber before and after the cleaning gas is supplied is 7 to 400 Torr.

11. A substrate processing apparatus as recited in claim 10, wherein
a pressure difference in the processing chamber before and after the cleaning gas is supplied is 7 to 30 Torr.

12. A substrate processing apparatus as recited in claim 6, wherein
a pressure difference in the processing chamber before and after the cleaning gas is supplied is 7 to 400 Torr.

13. A substrate processing apparatus as recited in claim 12, wherein
a pressure difference in the processing chamber before and after the cleaning gas is supplied is 7 to 30 Torr.

14. A substrate processing apparatus as recited in claim 1, wherein the cleaning gas is halogen-based gas.

15. A substrate processing apparatus as recited in claim 14, wherein the cleaning gas is a gas selected from a group consisting of NF₃, F₂, HF, ClF₃ and BCl₃.

16. A substrate processing apparatus as recited in claim 6, wherein the cleaning gas is halogen-based gas.

17. A substrate processing apparatus as recited in claim 16, wherein the cleaning gas is a gas selected from a group consisting of NF₃, F₂, HF, ClF₃ and BCl₃.

18. A substrate processing apparatus as recited in claim 6, wherein
the cleaning gas supplied to the first gas supply path and the cleaning gas supplied to the second gas supply path have different chemical formulas from each other.

19. A substrate processing apparatus, comprising:
a processing chamber to process a substrate;
an exhaust path to exhaust the processing chamber;
an exhaust device to exhaust atmosphere in the processing chamber through the exhaust path;
an exhaust valve to open and close the exhaust path;
a raw material gas supply member to supply raw material gas which contributes to film forming into the processing chamber;
a cleaning gas supply member to supply cleaning gas which removes an accretion, which adheres to an inside of the processing chamber with the raw material gas being supplied, the cleaning gas supply member comprising:
a first supply path to supply the cleaning gas;
a second supply path branching from the first supply path and comprising a first gas supply valve, a first gas reservoir to store the cleaning gas and the second gas supply valve in this order from upstream;
a third supply path branching from the first supply path and comprising a third gas supply valve, a second gas reservoir to store the cleaning gas and the fourth gas supply valve in this order from upstream; and
a fourth supply path to which the second supply path and the third supply path are joined to supply the cleaning gas to the processing chamber; and
a control section which controls the exhaust valve, the first gas supply valve, the second gas supply valve, the third gas supply valve and the fourth gas supply valve to repeat predetermined times a step of supplying the cleaning gas to the second supply path to store the cleaning gas in the first gas reservoir and supplying the cleaning gas stored in the first gas reservoir to the processing chamber from the first gas reservoir with exhaustion of the processing chamber being stopped, and a step of supplying the cleaning gas to the third supply path to store the cleaning gas in the second gas reservoir and supplying the cleaning gas stored in the second gas reservoir to the processing chamber from the second gas reservoir with exhaustion of the processing chamber being stopped.

20. A semiconductor device manufacturing method, comprising:
supplying raw material gas to a substrate accommodated in a processing chamber to form a desired film on the substrate; and
supplying cleaning gas to the processing chamber with exhaustion of the processing chamber being stopped.
